(19) United States
(12) Patent Application Publication
(10) Pub. No.: US 2010/0272977 A1
(43) Pub. Date: Oct. 28, 2010

(54) CHARGE EXCHANGE DEVICE

(75) Inventors: Masataka HASEGAWA, Tsukuba-shi (JP); Takeshi SAITO, Tsukuba-shi (JP); Kazutomo SUENAGA, Tsukuba-shi (JP); Sumio IIJIMA, Tsukuba-shi (JP)

Correspondence Address: SUGHRUE-265550, 2100 PENNSYLVANIA AVE. NW, WASHINGTON, DC, 20037-3213, US

(73) Assignee: National Institute of Advanced Industrial Science and Technology, Tokyo (JP)

(21) Appl. No.: 12/765,279

(22) Filed: Apr. 22, 2010

(30) Foreign Application Priority Data
Apr. 23, 2009 (JP) 2009-104606

(51) Int. Cl. B32B 7/02; B32B 5/02; C23C 16/513

(52) U.S. Cl. 428/218; 442/59; 427/575

(57) ABSTRACT

The present invention provides a charge exchange member having a new function, which solves problems of fragility of a diamond thin film and a low electron density of a CNTS that are challenges of a charge exchange foil. The present invention relates to a charge exchange device comprising a diamond thin film and a non-woven carbon nanotube sheet, in which the diamond thin film is deposited on the non-woven carbon nanotube sheet.

### CROSS-REFERENCE TO RELATED APPLICATIONS

This application claims priority from Japanese Patent Application No. 2009-104606 filed on Apr. 23, 2009, the entire subject matter of which is incorporated herein by reference.

### BACKGROUND OF THE INVENTION

1. Field of the Invention

The present invention relates to a charge exchange device of a high-energy particle accelerator.

2. Background Art

Conventionally, in the field of nuclear physics, in order to obtain high-energy particles (ions) as means for nuclear structure analysis, development of various particle accelerators has been promoted, and an increase in the size of accelerators has been promoted.

Moreover recently, in a wide range of fields of ion doping in semiconductor material production, ion beam processing for steel modification, ion beam analysis of hydrogen in materials where detection is generally considered difficult, ion beam analysis for material composition and structural analysis, materials science, biological or medical science, and archaeology, such as isotope separation for age determination, and the like, relatively small-sized accelerators have also been actively used.

Conventionally, amorphous carbon thin films have been used as charge exchange foils of high-energy particle (ion) accelerators. For acceleration of particles (ions), for the purpose of an improvement in acceleration efficiency and handling for convergence, deflection or the like of particle beams, a charge exchange foil which strips off electrons from accelerating particles (ions) is used. This uses a phenomenon that when particles penetrate a thin film at high speed, due to collision of electrons bound to the particles and electrons in the charge exchange foil, the electrons bound to the particles are released from the binding, so that the valence of particles increases. More specifically, due to collision of electrons that resides therein and particles passing therethrough, a charge exchange foil has an effect of stripping off electrons bound to the particles, thereby imparting a charge to the particles.

Accordingly, in principle, the higher the electron density in the charge exchange foil is, the higher the charge exchange efficiency is. However, on the other hand, for use of particles in experimentation or measurement, it is necessary in particular for particles to penetrate the charge exchange foil with almost no loss in energy. The charge exchange foil is thus generally an extremely thin free-standing film. As a charge exchange device material that satisfies the above conditions, an amorphous carbon film which is a thin-film material made from carbon has been used.

An amorphous carbon film typically has a small strength, and is damaged in a short time by irradiation of particle beams, and thus frequent replacement is necessary. Accordingly, it has been a challenge to increase the use efficiency of the accelerator to provide the charge exchange foil with a longer service life, and development of a carbon material excellent in mechanical strength and high-temperature stability has been demanded. In order to improve this situation, use of a diamond thin film that is higher in hardness and thermal conductivity than the amorphous carbon film has been studied. In particular, the diamond thin film has a high electron density compared to the amorphous carbon film, and thus has been expected as a highly efficient charge exchange device.

However, a diamond thin film of a few microns in thickness is fragile, and handling thereof is difficult. Therefore, usage as a free-standing film has not yet been realized. Development of a method for counterbalancing the fragility of a diamond thin film to make handling thereof easy has been demanded.

### SUMMARY OF THE INVENTION

In recent years, a carbon nanotube (herein after may be referred to as “CNT”) has been focused as a lightweight and high-strength material made from carbon. The CNT is a hollow circular cylindrical carbon member having a diameter of a few nanometers. It is at present possible to form a non-woven carbon nanotube sheet (hereinafter may be referred to as “CNTS”), which is a sheet-like thin-film member, using CNTs. In particular, the CNTS is lightweight and has high strength and retains high thermal conductivity, and hence, usage as a charge exchange foil that improves the short service life of an amorphous carbon film is expected. However, the CNTS has a small electron density as compared to a diamond thin film, and therefore has a small charge exchange efficiency, which is a drawback.

The present invention has been made in view of such circumstances as in the above, and provides a charge exchange member having a new function, which solves problems of fragility of a diamond thin film and a low electron density of a CNTS that are challenges of a charge exchange foil.

As a result of intensive studies for achieving the above, the present inventors have discovered a new method for diamond nucleus generation on a CNTS substrate, and it has been revealed that a laminate of a CNTS and a diamond thin film can be thereby formed, and the obtained laminate can solve the above-mentioned problem of conventional arts.

More specifically, the charge exchange of high-energy particles is caused substantively by a collision of the high-energy particles with electrons in a thin film, however, for causing this collision of high-energy particles and electrons in the thin film at a sufficient frequency to bring about a highly efficient charge exchange, it is effective to laminate a thin film with a low electron density and a thin film with a high electron density, that is, to use a device comprising a laminate of thin films having different electron densities. This allows solving the problem of conventional charge exchange foils. In other words, by forming a laminate of a CNTS and a diamond thin film, fragility of the diamond thin film with a high electron density is counterbalanced by excellent strength of the CNTS, while a low electron density of the CNTS is counterbalanced by a diamond thin film layer, and this allows provision of a charge exchange member having a new function to solve the problems of fragility and a low electron density, which are conventional challenges. Hereinafter, in the present invention, a laminate of thin films will be referred to as a “charge exchange device.”

The present invention has been accomplished based on these findings, and includes the following embodiments.

[1] A charge exchange device comprising a laminate of thin films having different electron densities.

[2] A charge exchange device comprising a non-woven carbon nanotube sheet and a diamond thin film, in which the diamond thin film is deposited on the non-woven carbon nanotube sheet.

[3] The charge exchange device according to [2], wherein the diamond thin film is formed by a microwave surface-wave plasma CVD method.

[4] The charge exchange device according to [2], wherein the charge exchange device, in an X-ray diffraction spectrum by CuK_{α1} ray, has a peak at a Bragg's angle (2θ±0.3°) of 43.9° by incidence of X-ray from a surface of the diamond thin-film, and does not have a peak at a Bragg's angle (2θ±0.3°) of 43.9° by incidence of X-ray from a surface of the non-woven carbon nanotube sheet.

[5] The charge exchange device according to [2], wherein the charge exchange device, in an ultraviolet excitation Raman scattering spectrum with a wavelength of 244 nm, has a peak at wavenumbers of 1333±10 cm⁻¹ and 1587±10 cm⁻¹ by incidence of ultraviolet ray from a surface of the diamond thin-film, and has a peak at a wavenumber of 1587±10 cm⁻¹ by incidence of ultraviolet ray from a surface of the non-woven carbon nanotube sheet.

[6] The charge exchange device according to [4], wherein the charge exchange device, in an ultraviolet excitation Raman scattering spectrum with a wavelength of 244 nm, has a peak at wavenumbers of 1333±10 cm⁻¹ and 1587±10 cm⁻¹ by incidence of ultraviolet ray from a surface of the diamond thin-film, and has a peak at a wavenumber of 1587±10 cm⁻¹ by incidence of ultraviolet ray from a surface of the non-woven carbon nanotube sheet.

[7] A method for manufacturing a charge exchange device, which comprises depositing a diamond thin-film on a non-woven carbon nanotube sheet by a microwave surface-wave plasma CVD method.

[8] The method for manufacturing a charge exchange device according to [7], which comprises applying a dispersion of an ultrafine diamond particle to a surface of the non-woven carbon nanotube sheet to deposit the ultrafine diamond particle to the surface of the non-woven carbon nanotube sheet, prior to the microwave surface-wave plasma CVD method.

[9] The method for manufacturing a charge exchange device according to [8], wherein the ultrafine diamond particle is selected from the group consisting of a nano-crystalline diamond particle, a cluster diamond particle and a graphite cluster diamond particle.

In the charge exchange device comprising a laminate of a non-woven carbon nanotube sheet (CNTS) and a diamond thin film of the present invention, fragility of the diamond thin film is counterbalanced by excellent strength of the CNTS, and a low electron density of the CNTS is counterbalanced by a high electron density of a diamond thin film layer, and this allows solving the problem of a low strength of the diamond thin film and a low electron density of the CNTS that have conventionally been used as a charge exchange device.

### BRIEF DESCRIPTION OF THE DRAWINGS

FIG. 1 shows a view schematically showing a microwave surface-wave plasma CVD apparatus to be used for manufacturing a charge exchange device of the present invention.

FIG. 2 shows a sectional view showing an outline of a charge exchange device comprising a laminate of a non-woven carbon nanotube sheet and a diamond thin film of the present invention.

FIG. 3A shows a microscopy image of a non-woven carbon nanotube sheet.

FIG. 3B shows an enlarged microscopy image of a non-woven carbon nanotube sheet.

FIG. 4A shows a Raman scattering spectrum obtained by incidence from a surface deposited with a diamond thin film of the charge exchange device of the present invention.

FIG. 4B shows a Raman scattering spectrum obtained by incidence from a CNTS surface deposited with no diamond thin film of the charge exchange device of the present invention.

FIG. 5A shows an X-ray diffraction spectrum diagram by X-rays (CuK_{α1}) obtained by X-rays incident from the diamond thin-film side of the charge exchange device of the present invention (X-ray incident angle of 0.5 degrees, measuring increments of 0.05 degrees/step, measurement time per 1 step of 1 second).

FIG. 5B shows an X-ray diffraction spectrum diagram by X-rays (CuK_{α1}) obtained by X-rays incident from the diamond thin-film side of the charge exchange device of the present invention (X-ray incident angle of 0.5 degrees, measuring increments of 0.02 degrees/step, measurement time per 1 step of 120 seconds).

FIG. 5C shows an X-ray diffraction spectrum diagram by X-rays (CuK_{α1}) obtained by X-rays incident from the CNTS side of the charge exchange device of the present invention (X-ray incident angle of 0.5 degrees, measuring increments of 0.05 degrees/step, measurement time per 1 step of 1 second).

FIG. 5D shows an X-ray diffraction spectrum diagram by X-rays (CuK_{α1}) obtained by X-rays incident from the CNTS side of the charge exchange device of the present invention (X-ray incident angle of 0.5 degrees, measuring increments of 0.02 degrees/step, measurement time per 1 step of 150 seconds).

FIG. 6 shows a scanning electron microscopy image of the charge exchange device of the present invention.

FIG. 7 shows a high-resolution transmission electron microscopy (HRTEM) image of the charge exchange device of the present invention.

FIG. 8A shows a high-resolution transmission electron microscopy (HRTEM) image of the charge exchange device of the present invention.

FIG. 8B shows a diffraction image obtained from a part surrounded by a white square of the high-resolution transmission electron microscopy (HRTEM) image of the charge exchange device of the present invention, shown in FIG. 8A.

### REFERENCE SIGNS LIST

11: Diamond thin film
12: Non-woven carbon nanotube sheet
101: Plasma generating chamber
102: Slotted square microwave waveguide
103: Quartz window for introducing microwaves
104: Metallic support member that supports quartz window
105: Non-woven carbon nanotube (being film-forming substrate as well as carbon source)
106: Specimen stage for placing film-forming substrate
107: Cooling water supply and drainage pipe
108: Exhaust pipe
109: CVD process gas introduction pipe
110: Reaction furnace
111: Cooling water pipe

### DETAILED DESCRIPTION OF THE INVENTION

A charge exchange device is a device that brings about an effect that, when high-energy particles (ions) penetrate a thin film at high speed, electrons bound to the particles and electrons in the charge exchange device collide, and the electrons bound to the particles are released from the bound state to increase the valence of particles.

The charge exchange device of the present invention has a laminate structure of a non-woven CNTS with a low electron density and a diamond thin film with a high electron density. With regard to the non-woven CNTS with a low electron density, the non-woven CNTS preferably has an electron density of 0.9×10²³/cc to 3×10²³/cc, and more preferably has an electron density of 2×10²³/cc to 3×10²³/cc. Also, with regard to the diamond thin-film with a high electron density, the diamond thin-film preferably has an electron density of 6×10²³/cc to 9×10²³/cc, and more preferably 8×10²³/cc to 9×10²³/cc.

The charge exchange device comprising a laminate of a non-woven CNTS with a low electron density and a diamond thin film with a high electron density of the present invention can be realized for the first time by a CVD process using the CNTS itself being a laminate substrate as a carbon source for synthesis of the diamond thin film.

Hereinafter, details of the charge exchange device will be described, however, the present invention is not limited thereto.

### (Preparation of CNT Sheet)

The non-woven carbon nanotube sheet (CNTS) to be used in the present invention is in a thin-film form in which carbon nanotubes (CNTs) are irregularly and closely entangled with each other, and for instance, formed with a thin film like a non-woven fabric where CNTs are collected in bundles and are intricately intertwined with each other.

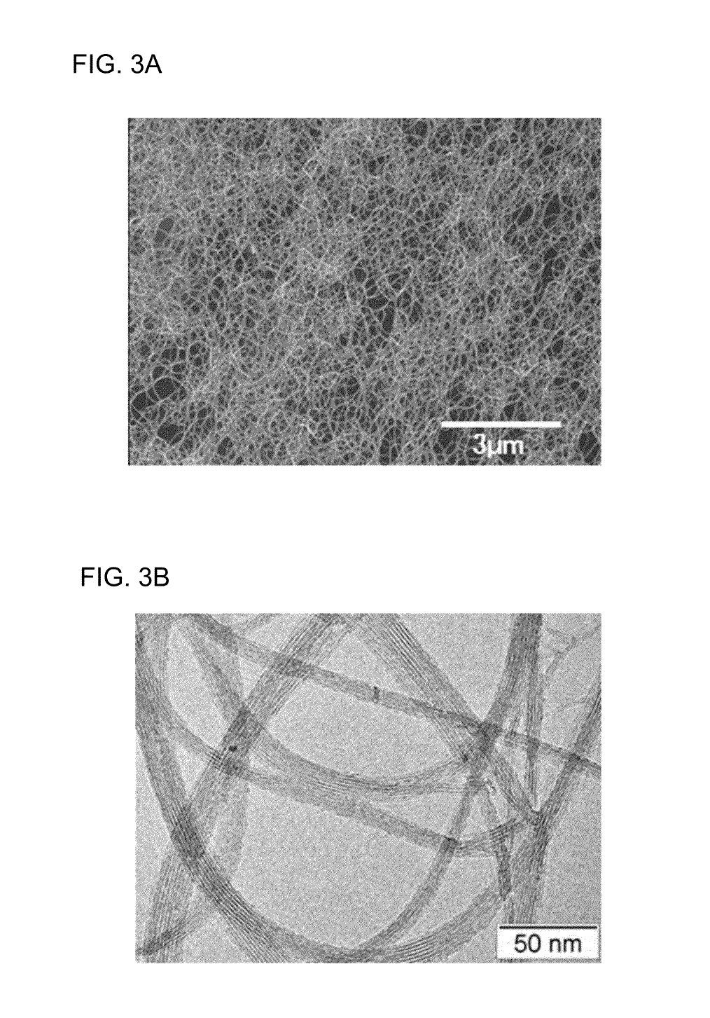

FIG. 3A shows a microscopy image of a non-woven carbon nanotube sheet, and FIG. 3B shows an enlarged microscopy image thereof.

In the present invention, in particular, a CNTS which has an electron density of preferably 0.9×10²³/cc to 3×10²³/cc, and more preferably 2×10²³/cc to 3×10²³/cc, has a specific gravity of preferably 0.3 g/cc to 1.0 g/cc, and has a film thickness of preferably 1 μm to 100 μm, is preferably used. In addition, such a CNTS can be prepared by an enhanced direct injection pyrolytic synthesis method, and the enhanced direct injection pyrolytic synthesis method are described in, for example, “Public Relations Department, National Institute of Advanced Industrial Science and Technology, ‘Beginning of Mass production of high-quality single wall carbon nano tube and sample distribution thereof’ [online], Feb. 13, 2007, National Institute of Advanced Industrial Science and Technology, [searched on Feb. 16, 2009], Internet <URL: http://www.aist.go.jp/aist_j/press_release/pr2007/pr20070213/pr20070213.html>”, herein incorporated by reference.

Moreover, the CNTS can also be obtained by the following steps, that is, the CNTs is dispersed in a solvent and the resulting dispersion is filtered through the membrane filter or the like to obtain a thin-film of CNTs on the membrane filter or the like, then the thin-film of CNTs is stripped from the membrane filter or the like after drying. The CNTS can be suitably used in the present invention. In addition, as the solvent used therein, examples thereof includes N-methyl-pyrrolidone (NMP) and dimethylformamide (DMF).

### (Diamond Thin-Film)

The diamond thin-film of the charge exchange device of the present invention has a film thickness of preferably 1 to 10 μm, and more preferably 2 to 10 μm, and has a specific gravity of preferably 2.0 to 3.0 g/cc, and more preferably 2.7 to 3.0 g/cc. In addition, the electron density of the diamond thin-film is preferably 6×10²³/cc to 9×10²³/cc, and more preferably 8×10²³/cc to 9×10²³/cc.

### (Lamination of CNT Sheet and Diamond Thin Film)

In the present invention, in order to deposit a diamond thin-film layer on a non-woven CNTS substrate, a microwave surface-wave plasma CVD process is preferably performed. Prior to the plasma CVD process, it is preferred to apply a dispersion liquid of ultrafine diamond particles to bond the ultrafine diamond particles to the substrate surface. The ultrafine diamond particle means a diamond particle generally having an average particle diameter of 4 to 100 nm, and more preferably 4 to 10 nm, and examples thereof include nano-crystalline diamond particles, cluster diamond particles, and graphite cluster diamond particles. The concentration of the dispersion liquid of the ultrafine diamond particles is preferably 1 wt % to 10 wt %, and more preferably 2.5 wt % to 5.0 wt %.

Ultrafine diamond particles such as nano-crystalline diamond particles are generally diamond that is produced by detonation synthesis or by pulverizing diamond synthesized at high temperature and high pressure. As examples of the nano-crystalline diamond, a colloidal solution for which nano-crystalline diamond produced by detonation synthesis is disposed in a solvent has already been distributed by NanoCarbon Research Institute Co., Ltd. and others, and nano-crystalline diamond powder produced by pulverization and that dispersed in a solvent have already been distributed by Tomei Diamond Co., Ltd. and others. The nano-crystalline diamond particles to be used in the present invention have an average particle diameter of preferably 4 nm to 100 nm, and preferably 4 nm to 10 nm. There is a detailed description of nano-crystalline diamond particles in, for example, the literature “Hiroshi Makita, New Diamond Vol. 12 No. 3, pp. 8-13 (1996)”, herein incorporated by reference.

The ultrafine diamond particles such as nano-crystalline diamond particles bonded to the substrate surface, in the plasma CVD process of the CNTS, function as starting points of diamond nucleus formation to trigger diamond thin-film formation, that is, seeds of diamond. Moreover, ultrafine diamond particles such as the nano-crystalline diamond particles bonded to the substrate surface function as anchoring micro diamond particles that enhance the adhesion strength of the diamond thin-film layer to the CNTS substrate. When the nano-crystalline diamond particles are applied to the substrate, a spin coater or a sprayer can be used.

On the other hand, prior to the bonding operation of ultrafine diamond particles such as nano-crystalline diamond particles, in order to facilitate the bonding operation and the plasma CVD process operation, the CNTS is preferably soaked in hexane or the like to be wet, stuck on a silicon wafer, and dried. It is confirmed that after drying, the CNTS is still stuck on the silicon wafer with a strength sufficient for the operations.

In the present invention, after ultrafine diamond particles are bonded to the CNTS substrate, a microwave surface-wave plasma CVD process is preferably performed in a microwave surface-wave plasma CVD apparatus.

In the microwave surface-wave plasma CVD treatment, as a CVD process gas, a gas mixture comprising a hydrogen gas, a CO₂ gas and a methane gas is generally used. The mixture ratio thereof (hydrogen gas:CO₂ gas: methane gas) is preferably, in terms of mole ratio, 80 to 45%:10 to 25%:10 to 30%, and more preferably 70 to 55%:15 to 20%:15 to 25%.

The pressure in a reaction furnace after introducing the CVD process gas to the reaction furnace is preferably maintained from 20 to 500 Pa, more preferably from 100 to 400 Pa.

In the microwave surface-wave plasma CVD treatment, the CNTS substrate in the plasma treatment is generally controlled so as to have a temperature of 30 to 100° C. and more preferably 30 to 60° C. By maintaining the temperature of the CNTS substrate within the above range, a carbon component tends to be suitably released, and the released carbon component tends to act as a carbon source for diamond deposition, and the diamond deposition to the CNTS substrate tends to be suitably performed. The temperature of the substrate during the plasma process can be measured by making an alumel-chromel thermocouple contact the substrate surface. When the CNTS substrate reaches a high temperature during the plasma process, the action of plasma on the CNTS substrate tends to become excessive. More specifically, an etching effect due to the CNTS substrate being exposed to the plasma becomes excessively strong, so that the CNTS may disappear. For example, when the temperature of the CNTS substrate is 500° C., the substrate may disappear as a result of a few minutes of exposure to the plasma. For preventing the disappearance of the CNTS, it is preferable to keep the temperature at 100° C. or less. Even at 100° C. or less, due to the action of plasma, the CNTS substrate may receive an etching effect to an extent not sufficient to lead to disappearance, and a carbon component suitable for diamond deposition may be released from the CNTS substrate.

The time of the plasma CVD treatment depends on the thickness of the diamond thin-film deposited, but the suitable deposition rate is preferably 40 to 500 nm/hr, and more preferably 200 to 500 nm/hr.

Thus, a charge exchange device comprising a laminate of thin films having different electron densities of the diamond thin film with a high electron density and the CNTS with a low electron density can be prepared.

The charge exchange device of the present invention preferably has, in an ultraviolet excitation Raman scattering spectrum with a wavelength of 244 nm, a peak at wavenumbers of 1333±10 cm⁻¹ and 1587±10 cm⁻¹ by incidence of ultraviolet ray from a surface of the diamond thin-film, and has a peak at a wavenumber of 1587±10 cm⁻¹ by incidence of ultraviolet ray from a surface of the non-woven carbon nanotube sheet. The peak centered at a Raman shift of 1333 cm⁻¹ is attributed to sp³ carbon bonds, and indicates that the carbon film deposited by a plasma CVD process on the CNTS in the present example is diamond. The peak centered on a Raman shift of 1587 cm⁻¹ generally has a full width at half maximum (FWHM) of approximately 45 cm⁻¹ to 60 cm⁻¹, preferably 50 to 55 cm⁻¹, and the peak centered on a Raman shift of 1333 cm⁻¹ generally has a full width at half maximum (FWHM) of approximately 20 cm⁻¹ to 40 cm⁻¹, preferably 25 to 35 cm⁻¹. The ultraviolet excitation Raman scattering spectrum can be measured according to the method described below.

The charge exchange device of the invention preferably has, in an X-ray diffraction spectrum by CuK_{α1} ray, a peak at a Bragg's angle (2θ±0.3°) of 43.9° by incidence of X-ray from a surface of the diamond thin-film, and does not have a peak at a Bragg's angle (2θ±0.3°) of 43.9° by incidence of X-ray from a surface of the non-woven carbon nanotube sheet. In X-ray diffraction by CuK_{α1} rays, diamond has been known as a carbonaceous substance having a peak at 20 of 43.9°, and this peak is identified to be (111) reflection of diamond. The X-ray diffraction spectrum by CuK_{α1} ray can be measured according to the method described below.

### Example

The present invention is to be described more specifically with reference to examples but the invention is not restricted to the following example and can be practiced with appropriate modifications in a range capable of conforming to the gist of the invention that has been described previously and to be described later, and all of them are contained within the technical range of the invention.

In the present Example, a charge exchange device as shown in FIG. 2 which shows a sectional view showing a construction thereof is prepared. As shown in FIG. 2, the charge exchange device has a laminate structure of a non-woven carbon nanotube sheet (12) and a diamond thin film (11).

A non-woven carbon nanotube sheet (CNTS) having the electron density of 3×10²³/cc, the specific gravity of 1.0 g/cc, and the film thickness of 2 μm was used. The non-woven carbon nanotube sheet was in a thin-film form in which carbon nanotubes (CNTs) were irregularly and closely entangled with each other, and formed with a thin film like a non-woven fabric where CNTs were collected in bundles and were intricately intertwined with each other. FIG. 3A shows a microscopy image of the non-woven carbon nanotube sheet, and FIG. 3B shows an enlarged microscopy image thereof.

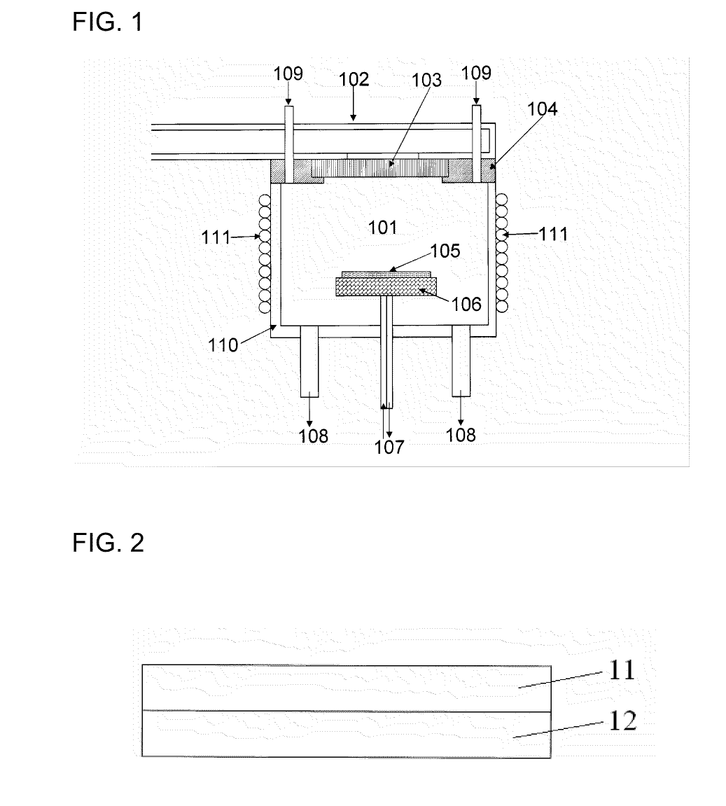

FIG. 1 shows a view schematically showing the microwave surface-wave plasma CVD apparatus which was used in this Example. The apparatus includes a metallic reaction furnace (110) having an upper end of which is opened, a quartz window (103) for introducing microwaves, which is air-tightly attached to an upper end portion of the reaction furnace (110) via a metallic support member (104), and a slotted square microwave waveguide (102) attached to an upper portion of the quartz window.

In addition, the reaction furnace (110) comprises a plasma generating chamber (101) inside, and a specimen stage (106) is set on the plasma generating chamber (101), and CNTS (105) is placed on the specimen stage (106). A CVD process gas introduction pipe (109) and an exhaust pipe (108) are connected to the reaction furnace. Also, a cooling water pipe (111) is set around the reaction furnace, and cooling water can be supplied thereto to cool the reaction furnace. In addition, cooling water can be supplied through a cooling water supply and drainage pipe (107) to cool the specimen.

In order to deposit a diamond thin-film layer on the non-woven CNTS substrate, a microwave surface-wave plasma CVD process was performed. Prior to the plasma CVD process, a dispersion liquid of ultrafine diamond particles including nano-crystalline diamond particles, cluster diamond particles, and graphite cluster diamond particles was applied to the non-woven CNTS substrate to bond the ultrafine diamond particles to the substrate surface. The concentration of the dispersion liquid of the ultrafine diamond particles was 2.5 wt %.

The ultrafine diamond particles such as nano-crystalline diamond particles bonded to the substrate surface, in the plasma CVD process of the CNTS, function as starting points of diamond nucleus formation to trigger diamond thin-film formation, that is, seeds of diamond. Moreover, ultrafine diamond particles such as the nano-crystalline diamond particles bonded to the substrate surface function as anchoring micro diamond particles that enhance the adhesion strength of the diamond thin-film layer to the CNTS substrate.

On the other hand, prior to the bonding operation of ultrafine diamond particles, in order to facilitate the bonding operation and plasma CVD process operation, the CNTS was soaked in hexane to be wet, stuck on a silicon wafer, and dried. It was confirmed that after drying, the CNTS was still stuck on the silicon wafer with strength sufficient for the operations.

In this Example, after ultrafine diamond particles were bonded to the CNTS substrate, a microwave surface-wave plasma CVD process was performed in a microwave surface-wave plasma CVD apparatus. The plasma CVD treatment was conducted by using the microwave surface-wave plasma CVD apparatus schematically shown in FIG. 1 as described above.

The substrate obtained in the above-mentioned step was placed inside of the reaction furnace (110), and the CVD process was performed. Processing procedures are as follows.

The CNTS (105) bonded with ultrafine diamond particles were placed on a specimen stage (106) provided in a plasma generating chamber (101) within the microwave surface-wave plasma CVD reaction furnace (110). Next, the inside of the reaction furnace was evacuated to 1×10⁻³ Pa or less through an exhaust pipe (108). A cooling water pipe (111) was set around the reaction furnace, and cooling water was thereto supplied to cool the reaction furnace. Moreover, the specimen stage was made of copper, and cooling water was supplied through a cooling water supply and drainage pipe (107) to cool the specimen.

The height of the specimen stage was adjusted so that the distance between the quartz window (103) and the CNTS substrate became 132 mm.

Next, a CVD process gas was introduced into the reaction furnace through a CVD process gas introduction pipe (109). The CVD process gas was a mixture gas of 63% by mol of hydrogen gas, 17% by mol of CO₂ gas, and 20% by mol of methane gas. The pressure inside the reaction furnace was held at 400 Pa by means of a gas control valve connected to the exhaust pipe (108). In this regard, as described above, from the CNTS (105) placed on the specimen stage, a carbon component is released due to the plasma CVD process to be described below, and the carbon component acts as a carbon source for diamond deposition. Without the action of the CNTS substrate as a carbon source, diamond deposition on the CNTS substrate is impossible. The release of a carbon component from the CNTS is controlled by the temperature of the CNTS substrate during the plasma process, and therefore in the present invention, the temperature control of the CNTS substrate during the plasma process is most important.

Plasma was generated at a microwave power of 1.5 kW, and the plasma CVD process of the CNTS substrate (105) was carried out. The temperature of the substrate during the plasma process was measured by making an alumel-chromel thermocouple contact the substrate surface. The temperature of the CNTS substrate was approximately 40° C. throughout the plasma CVD process. When the CNTS substrate reaches a high temperature during the plasma process, the action of plasma on the CNTS substrate becomes excessive. More specifically, an etching effect due to the CNTS substrate being exposed to the plasma becomes excessively strong, so that the CNTS may disappear. For example, when the temperature of the CNTS substrate is 500° C., the substrate may disappear as a result of exposure to the plasma for a few minutes. Accordingly, it is important to control the temperature of the base material carefully. For preventing the disappearance of the CNTS, it is necessary to keep the temperature at 100° C. or less. Even at 100° C. or less, due to the action of plasma, the CNTS substrate receives an etching effect to an extent not sufficient to lead to disappearance, and a carbon component suitable for diamond deposition is released from the CNTS substrate. As a result of the above plasma CVD process, a diamond thin film was laminated on the CNTS substrate, and a laminate of the CNTS and the diamond thin film was formed.

Under the conditions of the plasma CVD process of the Example, a diamond thin film with a thickness of approximately 2 μm was deposited by an 8 hour process. The diamond thin-film had a specific gravity of 3.0 g/cc and an electron density of 9×10²³/cc.

Thus, a charge exchange device comprising a laminate of thin films having different electron densities of the diamond thin film with a high electron density and the CNTS with a low electron density was prepared.

### (Evaluation: UV Raman Spectroscopy)

Measurement of a Raman scattering spectrum was conducted for the charge exchange device having a laminate structure of a CNTS and a diamond thin film of the present invention. An ultraviolet excitation spectrometer, NRS-1000UV manufactured by JASCO Corporation was used for the measurement, and a UV-laser with a wavelength of 244 nm (Ar ion laser 90C FreD manufactured by Coherent Inc.) was used for excitation light. The power of the laser source was 100 mW, and a beam attenuator was not used. The aperture was set to 200 μm. The measurement was performed twice with an exposure time of 60 seconds and 120 seconds, and results of the measurement were integrated to obtain a spectrum. The apparatus was calibrated with high-temperature and high-pressure synthetic single crystal diamond (DIAMOND WINDOW, Type: DW005 for Raman, Material: SUMICRYSTAL, manufactured by Sumitomo Electric Industries, Ltd.), which is a standard specimen for Raman scattering spectroscopy. The peak position of the Raman spectrum in the standard specimen was adjusted to a Raman shift of 1333 cm⁻¹. Standard computer software of this apparatus, Spectra Manager for Windows (registered trademark) 95/98 ver. 1.00 manufactured by JASCO Corporation was used for the measurement and the analysis.

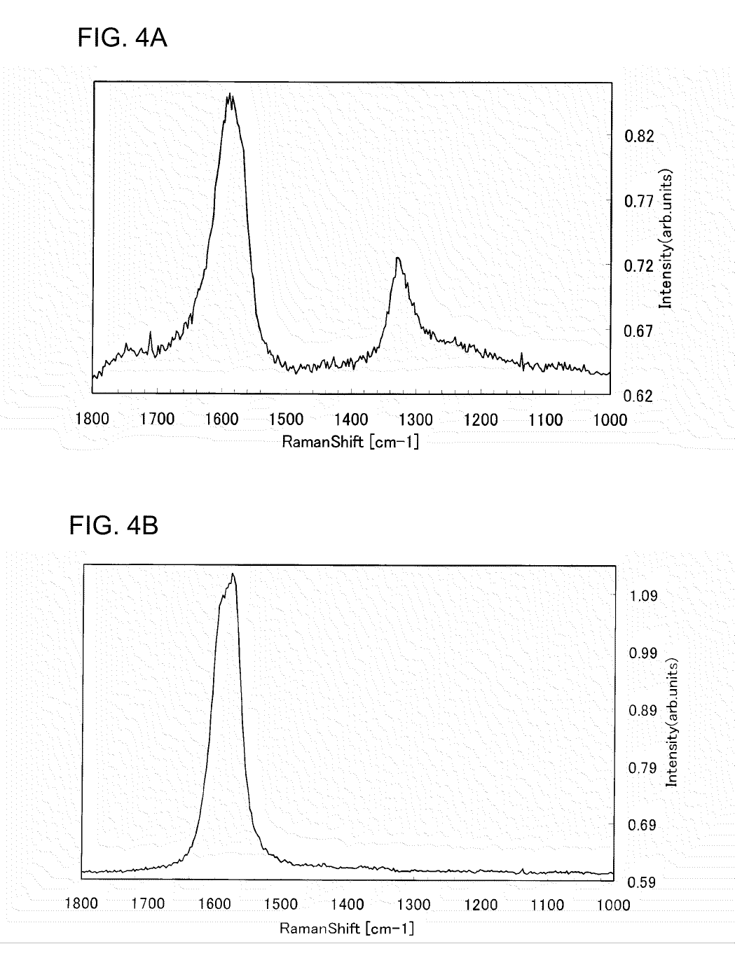

A typical measured Raman scattering spectrum is shown in FIG. 4A and FIG. 4B. The measured specimen is a diamond thin film having a thickness of approximately 2 μm prepared on a 20 mm square CNTS by the method mentioned above.

FIG. 4A shows a spectrum obtained by excitation light incident from the surface of a deposited diamond thin film, and FIG. 4B shows a spectrum obtained by excitation light incident from the surface not deposited with a diamond thin film, that is, a CNTS surface. In the Raman scattering spectrum obtained by incidence from the surface deposited with a diamond thin film shown in FIG. 4A, two distinct peaks were observed centered at Raman shifts of 1328 cm⁻¹ and 1582 cm⁻¹. On the other hand, in the Raman scattering spectrum obtained by incidence from the CNTS surface not deposited with a carbon film shown in FIG. 4B, although a distinct peak was observed centering at a Raman shift of 1582 cm⁻¹, a peak centering at a Raman shift of 1328 cm⁻¹ as in the Raman scattering spectrum obtained by incidence from the surface deposited with a diamond thin film shown in FIG. 4A was not observed. The peak centered at a Raman shift of 1328 cm⁻¹ is attributed to sp³ carbon bonds, and indicates that the carbon film deposited by a plasma CVD process on the CNTS in the present example is diamond.

The peak centered on a Raman shift of 1582 cm⁻¹ had a full width at half maximum (FWHM) of approximately 45 cm⁻¹ to 60 cm⁻¹, and the peak centered on a Raman shift of 1328 cm⁻¹ had a full width at half maximum (FWHM) of approximately 20 cm⁻¹ to 40 cm⁻¹.

### (Evaluation: X-Ray Diffraction)

The charge exchange device comprising a laminate structure of a CNTS and a diamond thin film of the present invention was observed by X-ray diffraction. In the following, details of the measurement will be described.

The X-ray diffraction apparatus used is an X-ray diffraction measurement apparatus, RINT2100 XRD-DSCII manufactured by Rigaku Corporation, and the goniometer used is Ultima III, a horizontal goniometer manufactured by Rigaku Corporation. A multi-purpose specimen stage for a thin-film standard was attached to the goniometer. The measured specimen is a laminate of a CNTS and a diamond thin film prepared by the method mentioned above. This specimen cut out in a 5 mm square was stuck on a silicon wafer with a thickness of 0.5 mm, and an X-ray diffraction measurement was conducted. The measurement was conducted by sticking this CNTS-diamond thin-film laminate on the silicon wafer so that its CNTS surface faced upward and making X-rays incident from the CNTS surface, and by sticking the laminate so that its diamond thin-film surface faced upward and making X-rays incident from the diamond thin-film surface, individually. As the X-rays, copper (Cu) K_{α1} rays were used. The application voltage and current of the X-ray tube were 40 kV and 40 mA, respectively. A scintillation counter was used for an X-ray detector.

At first, calibration of the scattering angle (2θ angle) was conducted by using a silicon standard specimen. Deviation of the 2θ angle was +0.02° or less. The measuring specimen was then fixed to the specimen stage, and the 2θ angle was adjusted to 0°, that is, a condition that X-rays are directly made incident into the detector, so that the X-ray incident direction and the specimen surface were in parallel and one half of the incident X-rays were shielded by the specimen. The goniometer was rotated from this state, and X-rays were irradiated at an angle of 0.5 degrees with respect to the specimen surface. This incident angle was fixed, while the 2θ angle was rotated from 10 degrees to 90 degrees in increments of 0.05 degrees, or in increments of 0.02 degrees, and the intensity of X-rays scattering from the specimen at each 2θ angle was measured. The computer program used for the measurement is RINT2000/PC software Windows (registered trademark) version, manufactured by Rigaku Corporation.

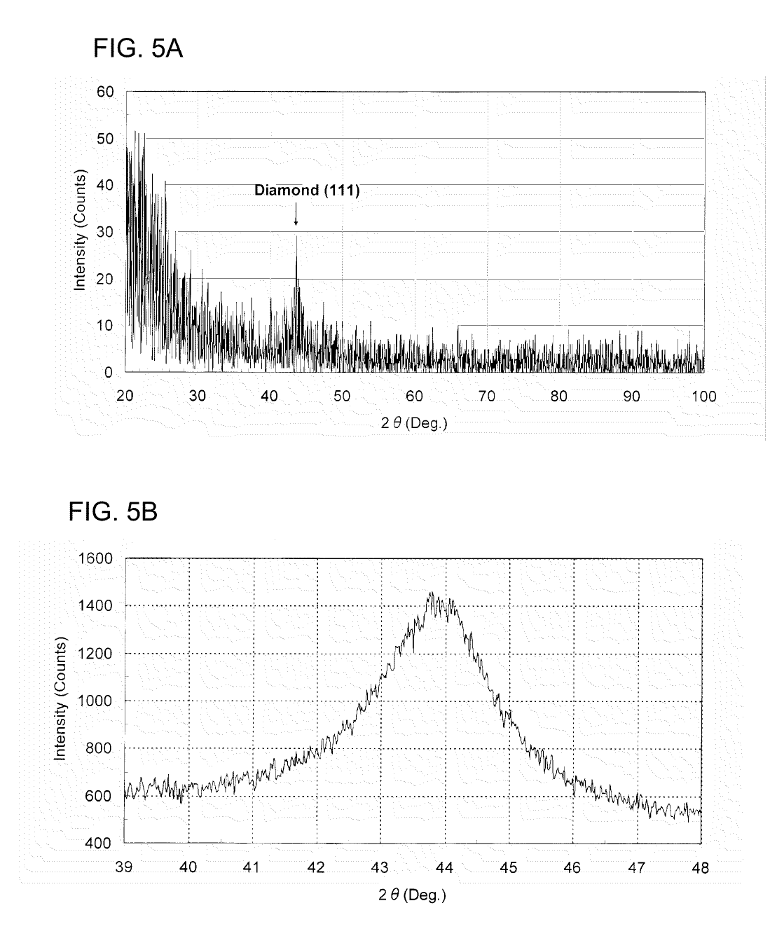

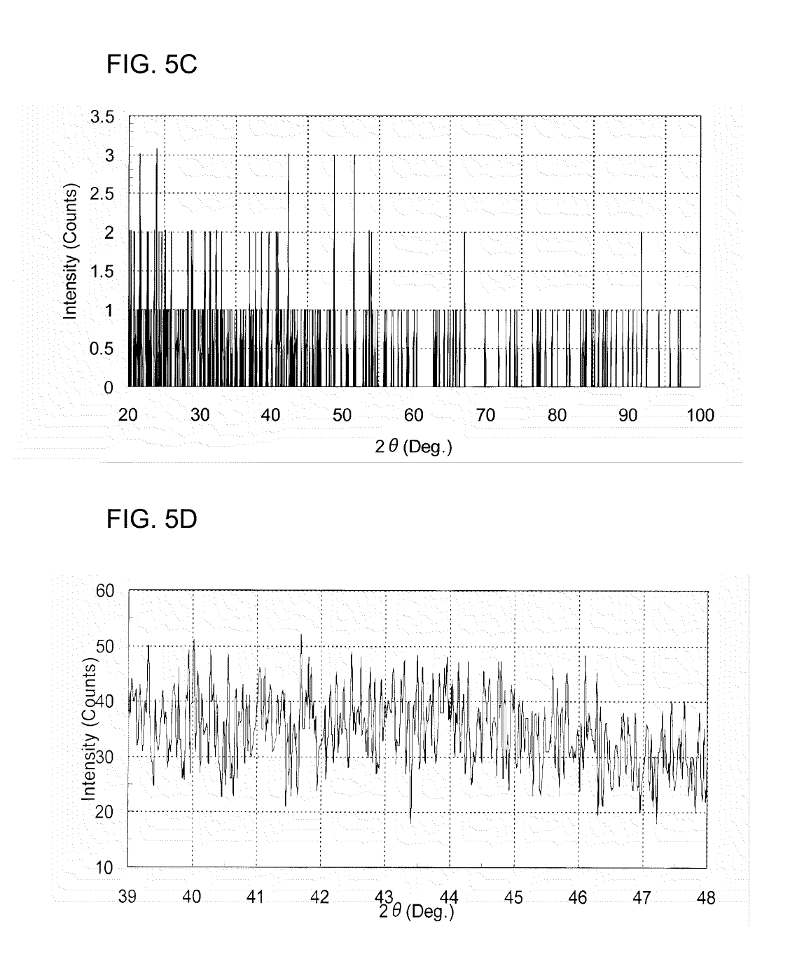

A spectrum of X-ray diffraction measured by making X-rays incident from the diamond thin-film side is shown in FIG. 5A and FIG. 5B. It can be understood that there is a distinct peak at 2θ of 43.9°. In X-ray diffraction by CuK_{α1} rays, diamond has been known as a carbonaceous substance having a peak at 20 of 43.9°, and this peak is identified to be (111) reflection of diamond.

As a result of an estimation of the size (average diameter) of diamond particles included in the diamond thin film of the CNTS-diamond thin-film laminate of the present invention, using the peak at 2θ of 43.9° of the X-ray diffraction spectrum shown in FIG. 5B, based on the peak width according to the Scherrer equation, which is usually used in X-ray diffraction, the size was approximately 5 nm. With regard to the Scherrer equation, refer to, for example, “Thin Film Handbook, edited by Japan Society for the Promotion of Science, 131st Committee Thin Film, Ohmusha Ltd., 1983, p. 375”, herein incorporated by reference.

On the other hand, a spectrum of X-ray diffraction measured by X-rays incident from the CNTS side is shown in FIG. 5C and FIG. 5D. A distinct peak at 2θ of 43.9°, which was observed when X-rays were made incident from the diamond thin-film side, could not be observed in this measurement. Although the measurement time spent for each one increment of 2θ was the same as or longer than that of the measurement when X-rays were made incident from the diamond thin-film side, the intensity of X-ray diffraction was small.

From the above, it has been revealed that the CNTS-diamond thin-film laminate of the present invention has a feature that, in X-ray diffraction by CuK_{α1} rays in the X-ray diffraction measurement where X-rays are made incident from the diamond thin-film side, a peak is observed at 2θ of 43.9°, while the intensity of X-ray diffraction at 2θ of 43.9° in the measurement where X-rays are made incident from the CNTS side is smaller than that when X-rays are made incident from the diamond thin-film side, and a distinct peak is not observed.

### (SEM Observation)

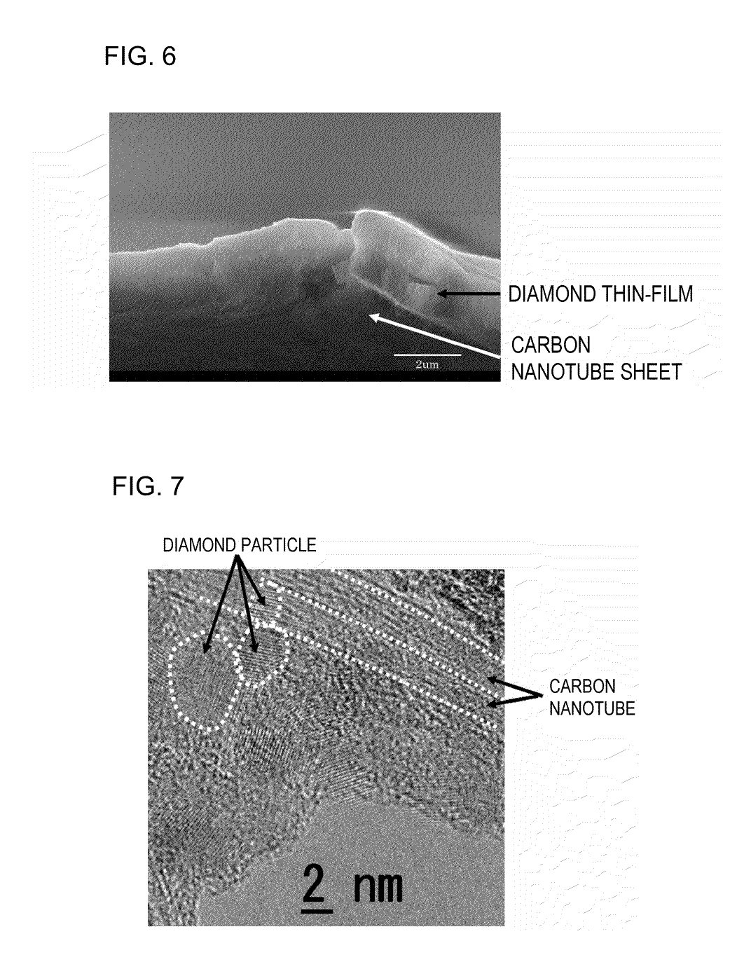

FIG. 6 is a sectional view of the charge exchange device having a laminate structure of a CNTS and a diamond thin film of the present invention observed through a scanning electron micrograph (SEM). The diamond thin-film section was imaged with bright contrast, and the CNTS was imaged with dark contrast. Further at a laminate interface between the diamond thin film and the CNTS, a fiber-like substance is observed, and this is CNTs that form the CNTS. It has been discovered that, in the CNTS-diamond thin-film laminate, the diamond thin film has a thickness of approximately 2 μm.

### (Transmission Electron Microscopy)

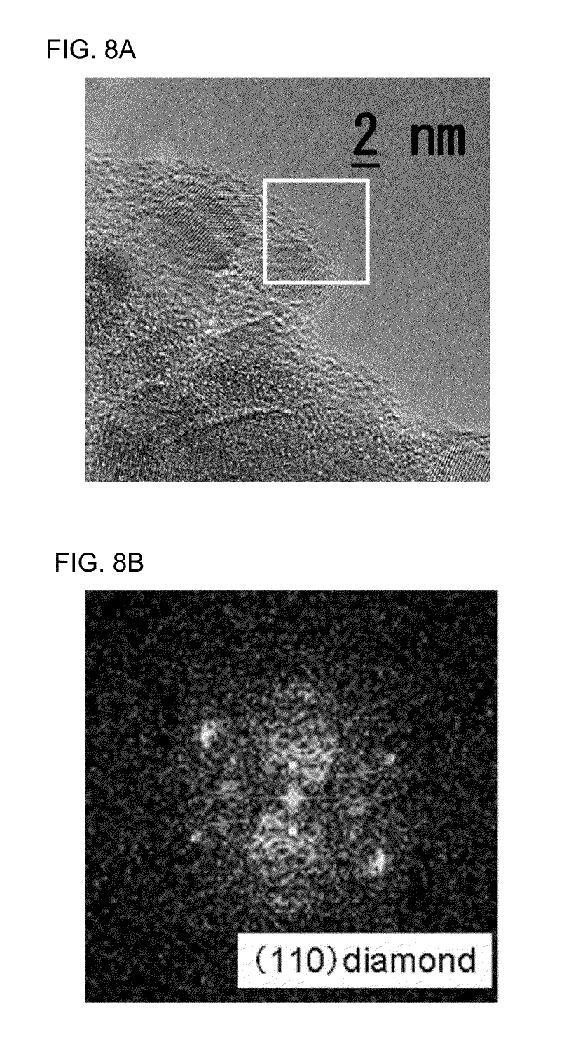

The charge exchange device having a laminate structure of a CNTS and a diamond thin film of the present invention was observed through a high-resolution transmission electron microscope (HRTEM). The HRTEM apparatus used was JEM-2100, a transmission electron microscope manufactured by JEOL Ltd., and the observation was conducted at an acceleration voltage of 120 kV. For the observation, a 5 mm square laminate of the present invention was ground in a mortar, and soaked in toluene or ethanol to be dispersed by means of an ultrasonic cleaner. The obtained fragments were collected to a micro-plastic grid, and observed. The results of observation are shown in FIG. 7, FIG. 8A, and FIG. 8B.

The fiber-like contrast (shown) in the upper portion of the screen of FIG. 7 is a carbon nanotube. In addition, from the fibrous contrast of the carbon nanotube toward the lower portion of the micrograph, diamond particles having a lattice fringe pattern can be confirmed (shown). Thus, the state where diamond particles are adhered to one CNT can be well understood.

Moreover, FIG. 8A shows a lattice fringe pattern obtained from another part of the same observation specimen, and FIG. 8B shows a diffraction image of the lattice fringe part surrounded by a white square shown in FIG. 8A. It has been confirmed from this diffraction experiment that the lattice fringes are diamond (111) surfaces. Moreover, it can be understood from these figures that the size of the diamond particles is approximately 4 nm to 5 nm.

Thus, it was understood that diamond particles with particle diameters of 4 nm to 5 nm are generated so as to adhere to the carbon nanotubes, and diamond particles are further deposited thereon, so that the laminate of the present invention is formed.

### (Evaluation: Mechanical Strength of Film)

In the present example, the laminate of the CNTS with a thickness of approximately 2 μm and the diamond thin film with a thickness of approximately 2 μm has a 20 mm-square area. In the case of preparation by a CVD process, the preparation was conducted with the CNTS stuck and fixed to a silicon wafer, however, even when the laminate stripped from the silicon wafer was handled with tweezers after the preparation, the laminate was never broken. The handling was very easy.

Conventionally, a diamond free-standing thin film with a thickness of 2 μm is very fragile, and easily broken when handled with tweezers. It has been discovered that the charge exchange device having a laminate structure of a CNTS and a diamond thin film of the present invention retains a sufficient mechanical strength as compared with the conventional diamond free-standing thin film.

1. A charge exchange device comprising a laminate of thin films having different electron densities.

2. A charge exchange device comprising a non-woven carbon nanotube sheet and a diamond thin film, in which the diamond thin film is deposited on the non-woven carbon nanotube sheet.

3. The charge exchange device according to claim 2, wherein the diamond thin film is formed by a microwave surface-wave plasma CVD method.

4. The charge exchange device according to claim 2, wherein the charge exchange device, in an X-ray diffraction spectrum by CuK_{α1} ray, has a peak at a Bragg's angle (2θ±0.3°) of 43.9° by incidence of X-ray from a surface of the diamond thin-film, and does not have a peak at a Bragg's angle (2θ±0.3°) of 43.9° by incidence of X-ray from a surface of the non-woven carbon nanotube sheet.

5. The charge exchange device according to claim 2, wherein the charge exchange device, in an ultraviolet excitation Raman scattering spectrum with a wavelength of 244 nm, has a peak at wavenumbers of 1333±10 cm⁻¹ and 1587±10 cm⁻¹ by incidence of ultraviolet ray from a surface of the diamond thin-film, and has a peak at a wavenumber of 1587±10 cm⁻¹ by incidence of ultraviolet ray from a surface of the non-woven carbon nanotube sheet.

6. The charge exchange device according to claim 4, wherein the charge exchange device, in an ultraviolet excitation Raman scattering spectrum with a wavelength of 244 nm, has a peak at wavenumbers of 1333±10 cm⁻¹ and 1587±10 cm⁻¹ by incidence of ultraviolet ray from a surface of the diamond thin-film, and has a peak at a wavenumber of 1587±10 cm⁻¹ by incidence of ultraviolet ray from a surface of the non-woven carbon nanotube sheet.

7. A method for manufacturing a charge exchange device, which comprises depositing a diamond thin-film on a non-woven carbon nanotube sheet by a microwave surface-wave plasma CVD method.

8. The method for manufacturing a charge exchange device according to claim 7, which comprises applying a dispersion of an ultrafine diamond particle to a surface of the non-woven carbon nanotube sheet to deposit the ultrafine diamond particle to the surface of the non-woven carbon nanotube sheet, prior to the microwave surface-wave plasma CVD method.

9. The method for manufacturing a charge exchange device according to claim 8, wherein the ultrafine diamond particle is selected from the group consisting of a nano-crystalline diamond particle, a cluster diamond particle and a graphite cluster diamond particle.
